(19) United States
(12) Patent Application Publication
(10) Pub. No.: US 2009/0320745 A1
(43) Pub. Date: Dec. 31, 2009

(54) HEATER DEVICE AND METHOD FOR HIGH PRESSURE PROCESSING OF CRYSTALLINE MATERIALS

(75) Inventors: Mark P. D'Evelyn, Goleta, CA (US); James S. Speck, Goleta, CA (US); Michael T. Coulter, Goleta, CA (US); Shuji Nakamura, Goleta, CA (US)

Correspondence Address: TOWNSEND AND TOWNSEND AND CREW, LLP, TWO EMBARCADERO CENTER, EIGHTH FLOOR, SAN FRANCISCO, CA, 94111-3834, US

(73) Assignee: SORAA, INC., Goleta, CA (US)

(21) Appl. No.: 12/484,095

(22) Filed: Jun. 12, 2009

Related U.S. Application Data
(60) Provisional application No. 61/075,723, filed on Jun. 25, 2008.

(51) Int. Cl. C30B 11/00; H05B 3/02; C30B 29/38

(52) U.S. Cl. 117/81; 219/539; 117/223

(57) ABSTRACT

An improved heater for processing materials or growing crystals in supercritical fluids is provided. In a specific embodiment, the heater is scalable up to very large volumes and is cost effective. In conjunction with suitable high pressure apparatus, the heater is capable of processing materials at pressures and temperatures of 0.2-2 GPa and 400-1200° C., respectively.

### CROSS-REFERENCES TO RELATED APPLICATIONS

This application claims priority to U.S. Provisional Application No. 61/075,723, filed Jun. 25, 2008, commonly assigned, and hereby incorporated by reference in its entirety herein.

### BACKGROUND OF THE INVENTION

The present invention relates generally to techniques for processing materials in supercritical fluids. More specifically, embodiments of the invention include techniques for thermal treatment and related heating devices associated with a material processing capsule disposed within a high-pressure apparatus/enclosure. Merely by way of example, the invention can be applied to growing crystals of GaN, AlN, InN, InGaN, AlGaN, and AlInGaN for manufacture of bulk or patterned substrates. Such bulk or patterned substrates can be used for a variety of applications including optoelectronic devices, lasers, light emitting diodes, photodetectors, solar cells, photoelectrochemical water splitting, and transistors.

Scientists have been synthesizing crystalline materials using high pressure techniques. As an example, synthetic diamonds are often made using high pressure and temperature conditions. Synthetic diamonds are often used for industrial purposes but can also be grown large enough for jewelry and other applications. Scientists and engineers also use high pressure to synthesize complex materials such as zeolites, such as ZSM-5. Moreover, geologists have also used high pressure techniques to simulate conditions and/or processes occurring deep within the earth's crust. High pressure techniques often rely upon supercritical fluids, herein referred to as SCFs.

Supercritical fluids may be used to process a wide variety of materials. Examples of SCF applications include extractions in supercritical carbon dioxide, decomposition of waste materials or biofuels in supercritical water, the growth of quartz crystals in supercritical water, and the synthesis of a variety of nitrides in supercritical ammonia. An example of a nitride material is gallium nitride for use with optical devices, such as light emitting diodes and laser devices, such as those used for optical data storage such as digital video disks and the like.

Conventional processes that employ supercritical fluids are commonly performed at high pressure and high temperature (also referred hereinafter as “HPHT”) within a pressure vessel or autoclave. Most conventional pressure vessels not only provide a source of mechanical support for the pressure applied to reactant materials and SCF, but also serve as a container for the supercritical fluid and material being processed. The processing limitations for such pressure vessels are typically limited to a maximum temperature in the range between about 400 degrees Celsius and 750 degrees Celsius and a maximum pressure in the range between about 0.2 gigapascal (also referred hereinafter as “GPa”) and 0.5 gigapascal. Although successful, drawbacks exist with these conventional processes. The aforementioned limitations of autoclaves can be overcome by separating the functions of chemical containment of the reaction environment and of mechanical support of associated pressure. The former function may be performed by a capsule. The latter function may be performed using a cool wall high pressure apparatus. The outer diameter of the capsule is separated from the inner diameter of the apparatus by a heating device. Although somewhat effective, the heater may not be capable of operating under the pressure and temperature conditions of the capsule without significant deformation, creep, compression, decomposition, breakage, or other forms of deterioration. Unfortunately, conventional processes still have limitations to overcome.

From the above, it is seen that techniques for improving a high pressure apparatus for crystal growth are highly desirable.

### BRIEF SUMMARY OF THE INVENTION

According to the present invention, techniques related to processing materials in supercritical fluids are provided. More specifically, embodiments of the invention include techniques for thermal treatment and related heating devices associated with a material processing capsule disposed within a high-pressure apparatus/enclosure. Merely by way of example, the invention can be applied to growing crystals of GaN, AlN, InN, InGaN, AlGaN, and AlInGaN for manufacture of bulk or patterned substrates. Such bulk or patterned substrates can be used for a variety of applications including optoelectronic devices, lasers, light emitting diodes, photodetectors, solar cells, photoelectrochemical water splitting for hydrogen generation, and transistors.

In a specific embodiment, the present invention provides an improved heater for processing materials or growing crystals in supercritical fluids is provided. In a specific embodiment, the heater is scalable up to very large volumes (e.g., larger than 0.3 liters, larger than 1 liter, larger than 3 liters, larger than 10 liters, larger than 30 liters, larger than 100 liters, and larger than 300 liters) and is cost effective. In conjunction with suitable high pressure apparatus, the heater is capable of processing materials at pressures and temperatures of 0.2-2 GPa and 400-1200° C., respectively. Of course, there can be other variations, modifications, and alternatives.

In an alternative specific embodiment, the present invention provides a heater for processing materials in supercritical fluids at high pressure and high temperature. The heater has at least two heating elements, which are often resistive wiring, and/or strips of metal material, and the like. The heater also has at least one tube. The heater optionally has a filler material, e.g., an alumina-based cement. The filler material comprises no more than 10% of the volume of the heater in a specific embodiment. In a specific embodiment, the heater is configured to be slidingly insertable between the outer diameter of a capsule and the inner diameter of a high pressure apparatus, which contains substantially no gaps larger than 0.1 inch in the minimum dimension within the volume defined by the inner diameter of the heater, the outer diameter of the heater, and the length of the capsule. In a specific embodiment, the heating elements are electrically isolated from both the inner and outer diameters of the heater. The density of the at least one tube is greater than 90% of the theoretical density according to a specific embodiment.

Still further, the present invention provides a heater for processing materials in supercritical fluids at high pressure and high temperature. The heater includes at least one inner tube member comprising a first region and a second region. In a specific embodiment, the inner tube member comprises an outer surface region and an inner surface region. The heater also includes at least two heating elements spatially disposed respectively in the first region and the second region. In a specific embodiment, the heater includes a thickness of insulating material overlying the two heating elements. In a preferred embodiment, the thickness of insulating material comprises an inner surface region and an outer surface region. The heater has an interface region provided between the outer surface region of the inner tube member and the inner surface region of the thickness of material. The interface region is substantially free from one or more voids and/or gaps. The one or more gaps and/or voids is capable of causing a failure including a crack and/or creep condition during an operation condition. The heater also has a cylindrical structure provided by at least the inner tube member, the two heating elements, and the thickness of insulating material to form a substantially incompressible sandwiched structure including at least the inner tube member, two heating elements, and thickness of insulating material. A length of no longer than about ten millimeters characterizes the thickness of the cylindrical structure from an inner portion of the cylindrical structure to an outer portion of the cylindrical structure. The inner portion of the cylindrical structure and the outer portion of the cylindrical structure are electrically isolated from the at least two heating elements. As used herein, the terms “substantially free of one or more voids and gaps” shall be interpreted by ordinary meaning as understood by one of ordinary skill in the art. As an example, the terms can include an operational meaning that any voids or gaps present are insufficient to cause a failure of the capsule and/or other elements of the high pressure apparatus. Of course, there can be other variations, modifications, and alternatives.

Moreover, the present invention provides an apparatus for high pressure crystal or material processing. The cylindrical capsule region comprises a first region and a second region, and a length defined between the first region and the second region. The apparatus has an annular heating member enclosing the cylindrical capsule region. The annular heating member includes at least one inner tube member comprising a first region and a second region. In a specific embodiment, the inner tube member comprises an outer surface region and an inner surface region. The heating member also includes at least two heating elements spatially disposed respectively in the first region and the second region. In a specific embodiment, the heating member includes a thickness of insulating material overlying the two heating elements. In a preferred embodiment, the thickness of insulating material comprises an inner surface region and an outer surface region. The heating member has an interface region provided between the outer surface region of the inner tube member and the inner surface region of the thickness of material. The interface region is substantially free from one or more voids and/or gaps. The one or more gaps and/or voids is capable of causing a failure including a crack and/or creep condition during an operation condition. The heating member also has a cylindrical structure provided by at least the inner tube member, the two heating elements, and the thickness of insulating material to form a substantially incompressible sandwiched structure including at least the inner tube member, two heating elements, and thickness of insulating material. A length of no longer than about ten millimeters characterizes the cylindrical structure from an inner portion of the cylindrical structure and an outer portion of the cylindrical structure. The inner portion of the cylindrical structure and the outer portion of the cylindrical structure are electrically isolated from the at least two heating elements. At least one or more annular ceramic members has a predetermined thickness disposed around a perimeter of the annular heating member. The annular member is made of a material having a compressive strength of about 0.5 GPa and greater and a thermal conductivity of about 4 watts per meter-Kelvin and less. The apparatus also has a high strength enclosure material disposed overlying the annular ceramic member.

In a specific embodiment, the present invention provides an apparatus for processing one or more materials. The apparatus has at least one heating element configured to transfer thermal energy to a process region within a capsule contained in a high pressure reactor. In a specific embodiment, the high pressure reactor is capable of withstanding a pressure of about 0.2 GPa and greater. The heating element is spatially disposed within a vicinity of the capsule and characterized by a thickness of less than about a predetermined amount about to maintain an exterior region of the capsule substantially free from damage while the process region of the capsule is subjected to a pressure of about 0.2 GPa and greater. In a preferred embodiment, the heating element is characterized by the thickness of less than the predetermined amount to have a deformation of less than about 2 mm and/or is characterized by the thickness of less than the predetermined amount to maintain the exterior region of the capsule free from a deformation of greater than about 2 mm.

Moreover, the present invention provides a method for forming crystalline material, GaN. The method includes using an apparatus for processing one or more materials comprising at least one heating element configured to transfer thermal energy to a process region within a capsule contained in a high pressure reactor. The high pressure reactor is capable of withstanding a pressure of about 0.2 GPa and greater. The heating element is spatially disposed within a vicinity of the capsule and characterized by a thickness of less than a predetermined amount to maintain an exterior region of the capsule substantially free from damage while the process region of the capsule is subjected to a pressure of about 0.2 GPa and greater. The method preferably forms and/or grows gallium nitride crystalline material within one or more portions of the process region.

Benefits are achieved over pre-existing techniques using the present invention. In particular, the present invention uses a high pressure treatment apparatus for growth of crystals such as GaN, AlN, InN, InGaN, and AlInGaN. Depending upon the embodiment, the present apparatus and method can be manufactured using conventional materials and/or methods known to one of ordinary skill in the art. In a specific embodiment, the present method and device can be used with a reduction or elimination of a filler material, which is used in conventional heater devices. Reduction and/or removal of the filler leads to a thinner heater device, which is more efficient and easier to use. Depending upon the embodiment, the present heater device can reduce deformation, improve overall process reliability and robustness, and the ease of capsule removal after processing a material. Additionally, the present heater device and method may provide simplification of the geometry, reducing cost; and optionally, utilization of a linear rather than helical geometry for heating elements, further improving reliability and decreasing costs. It is desirable to have a heater, a heating element for use in the heater, and an apparatus that includes a heater that can be used in a high pressure high temperature apparatus with little change in volume, allowing for repeat usage. Depending upon the embodiment, the heater device and method includes a method of making and/or using a heater, a heating element for use in the heater, and/or a high-pressure high temperature apparatus including a heater that can be used more than once. Depending upon the embodiment, one or more of these benefits may be achieved. These and other benefits may be described throughout the present specification and more particularly below.

The present invention achieves these benefits and others in the context of known process technology. However, a further understanding of the nature and advantages of the present invention may be realized by reference to the latter portions of the specification and attached drawings.

### BRIEF DESCRIPTION OF THE DRAWINGS

FIG. 1 is a simplified diagram of a heating device according to an embodiment of the present invention.

FIG. 2 is a simplified diagram of an alternative heating device according to an alternative embodiment of the present invention.

FIG. 3 is a simplified diagram of yet an alternative heating device according to an alternative embodiment of the present invention.

FIG. 4 is a simplified diagram of recessed region structures for heating devices according to alternative embodiments of the present invention.

FIG. 5 is a simplified top-view diagram of a heating device according to an embodiment of the present invention.

FIG. 6 is a simplified diagram of yet an alternative embodiment of a heating device according to an embodiment of the present invention.

FIG. 7 is a simplified diagram of yet an alternative embodiment of a heating device according to an embodiment of the present invention.

### DETAILED DESCRIPTION OF THE INVENTION

According to the present invention, techniques for processing materials in supercritical fluids are included. More specifically, embodiments of the invention include techniques for thermal treatment and related heating devices associated with a material processing capsule disposed within a high-pressure apparatus/enclosure. Merely by way of example, the invention can be applied to growing crystals of GaN, AlN, InN, InGaN, AlGaN, and AlInGaN for manufacture of bulk or patterned substrates. Such bulk or patterned substrates can be used for a variety of applications including optoelectronic devices, lasers, light emitting diodes, solar cells, photoelectrochemical water splitting for hydrogen generation, photodetectors, and transistors.

As background, we have provided some information about conventional techniques, which we have discovered. As an example, D'Evelyn et al., in US patent application 2008/0083741, disclosed a heater comprising an inner tube, an outer tube, at least one heating element, and a filler material between the inner and outer tubes in which the heating element is disposed. In one embodiment, a tubular heating assembly comprising a heating element and an outer tube, separated by a filler material, is bent into a serpentine shape and placed within a groove in an inner tube. In another embodiment, a metallic inner tube is coated with a ceramic layer, wrapped with at least one helical heating element, disposed within a metallic outer tube, and the space between the two tubes filled with a ceramic cement.

We later discovered that the D'Evelyn heater design has limitations that become progressively more significant the larger the heater becomes. That is, we believe that a larger heater design may lead to failures from defects in the heater caused by the design. Such failures may occur during operation of the conventional heater device or insertion and/or removal of the heater device from the high pressure apparatus. The D'Evelyn heater design does not offer a ready means to fabricate heaters with a wall thickness below ten mm, below six mm, below four mm, or below three mm. These and other limitations have been overcome by the present method and heater device. Further details of the present invention can be found throughout the present specification and more particularly below.

All ranges in the specifications and claims are inclusive of the endpoints and independently combinable. Numerical values in the specifications and claims are not limited to the specified values and may include values that differ from the specified value. The numerical values are understood to be sufficiently imprecise to include values approximating the stated values, allowing for experimental errors due to the measurement techniques known in the art and/or the precision of an instrument used to determine the values. Additionally, the range end limitations specified in the specification and claims, e.g., for temperature, pressure, concentration, etc., may be combined and/or interchanged and include sub-ranges that are logical sub-units.

Approximating language, as used herein throughout the specification and claims, may be applied to modify any quantitative representation that could permissibly vary without resulting in a change in the basic function to which it is related. “Free” may be used in combination with a term, and may include an insubstantial number, or trace amounts, while still being considered free of the modified term. The term “pitch” includes the distance from any point on a winding to the corresponding point on an adjacent winding measured parallel to the longitudinal axis. Castable refers to a capability to be formed into a particular shape by pouring into a mold. As used herein, the term “groove” includes an elongate depression and/or cut-out in a surface for receiving a heating element, wherein the depression and/or cut-out has a cross-sectional shape lacking sub-surface corners. As used herein, the term “channel” includes an elongate depression and/or cut-out in a surface for receiving a heating element, wherein the depression and/or channel has a cross-sectional shape that includes at least one sub-surface corner. As used herein, the term “recessed” region includes any groove and/or cut-out and/or depression, and the like, and should be interpreted under an ordinary meaning known by one of ordinary skill in the art. Of course, there can be other variations, modifications, and alternatives.

An apparatus according to an embodiment of the invention includes at least one tube and at least two heating elements proximal to the tube. In an embodiment, the heater includes a plurality of tubes. In another embodiment, a first tube and a second tube are elongate, each defining an axis. When placed in a coaxial relation relative to each other with the first tube disposed at least partially within the second tube, the first and second tube share a common axis. Each tube has an outward facing first surface and an inward facing second surface. The first surface of the first tube is spaced radially from the second surface of the second tube to define an annular space between the tubes, with an annular separation no larger than 0.1 inch, and preferably below 0.02 inch, and even more preferably below 0.01 inch. A clearance less than 0.002 inch or an interference fit may be provided between the first and second tubes, and the parts assembled by heating the second tube to a temperature greater than that of the first tube by 10 to 500 degrees Celsius and sliding them together and/or by pressing the tubes over one another. In an embodiment, one or both of the tubes can be cylindrical and/or formed from metal.

The second surface of the first tube can be sized, shaped and configured to receive a reaction capsule. Selection of materials and configuration allows for ease of release of the capsule after processing. In an embodiment, a reusable heater is provided that is capable of serially receiving a plurality of reaction capsules, and performing reactions in each of the capsules. In some embodiments, the second surface of the first tube has a root-mean-square surface roughness less than 1 millimeter (mm). In other embodiments, the second surface of the first tube has a root-mean-square surface roughness less than 0.1 millimeter, or less than 0.01 millimeter, or less than 0.001 millimeter. In some embodiments, the first surface of the second tube has a root-mean-square surface roughness less than 0.1 millimeter, or less than 0.01 millimeter, or less than 0.001 millimeter. In another embodiment, the at least one tube does not have any gaps, cracks, or discontinuities with a dimension that is larger than 0.1 inch. In another embodiment, the at least one tube does not have any gaps, cracks, or discontinuities with a dimension that is larger than 0.02 inch. In yet another embodiment, the at least one tube does not have any gaps, cracks, or discontinuities with a dimension that is larger than 0.01 inch.

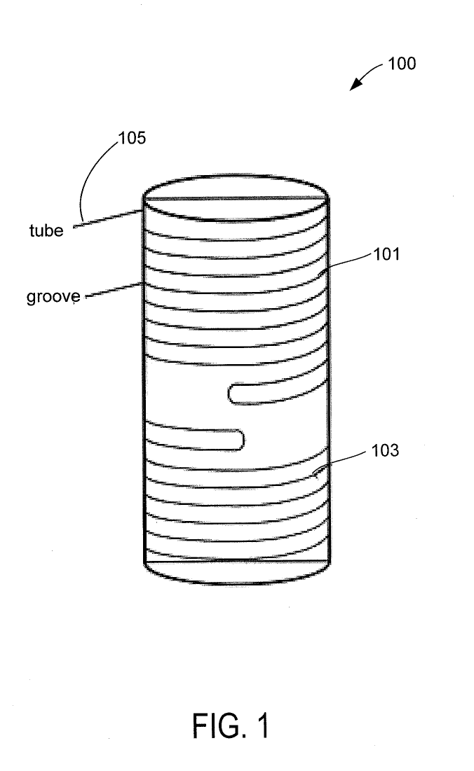

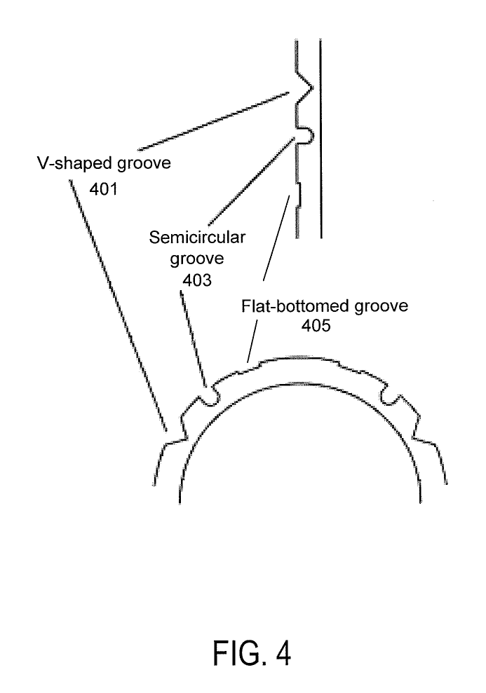

In a specific embodiment of the invention, a heating device 100 is shown in FIG. 1. This figure is merely an illustration and should not unduly limit the scope of the claims herein. One of ordinary skill in the art would recognize other variations, modifications, and alternatives. At least two grooves or channels 101, 103 are machined or ground into the first surface of the first tube 105. As shown in FIG. 1, the grooves or channels may comprise a double helix, with a loop in the middle so that both ends of the heating element placed therein exit from one end of the heater. In a specific embodiment, an upper section of the tube represents a first heating zone and a lower section of the tube represents a second heating zone, which is spatially separate from the first heating zone. Alternatively, the heating device can have multiple heating zones according to a specific embodiment. Referring now to FIG. 4, each groove or channel may have a V-shaped 401 cross section or be round 403 or flat 405 on the bottom of the groove. The latter shapes may be advantageous for receiving a round heating element wire or a flat heating element ribbon, respectively. In another embodiment, the groove or channel comprises a slot cut all the way through the tube. Additionally, the term “groove” should not be limiting and be interpreted by ordinary meaning according to one of ordinary skill in the art to include recessed regions or the like. Of course, there can be other variations, modifications, and alternatives.

Examples of metals for use in the tube include iron-based alloys, such as steel. In other embodiments, the tube can be formed from cermet, ceramic, or composite materials. In one embodiment, the first and second tubes include one or more high temperature superalloys exhibiting relatively low creep under operating conditions. Suitable superalloys include INCONEL 718 and HASTELLOY X, commercially available from Magellan Industrial Trading Company, Inc. (South Norwalk, Conn.), or others. In an embodiment, at least one of the first and second tubes comprises a ceramic with a density greater than 90% of the theoretical density. In another embodiment, at least one of the first and second tubes comprises a ceramic with a density greater than 95% of the theoretical density. In another embodiment, at least one of the first and second tubes comprises a ceramic with a density greater than 98% of the theoretical density. In an embodiment, at least one of the first and second tubes comprises alumina (Al₂O₃), mullite, or other suitable materials. In another embodiment, at least one of the first and second tubes comprises magnesia (MgO). In another embodiment, at least one of the first and second tubes comprises a glass, such as silica, borosilicate glass, a product sold as Vycor™, which is a tradename of Corning Incorporated, or an aluminosilicate glass, or the like. In still another embodiment, at least one of the first and second tubes comprises boron nitride.

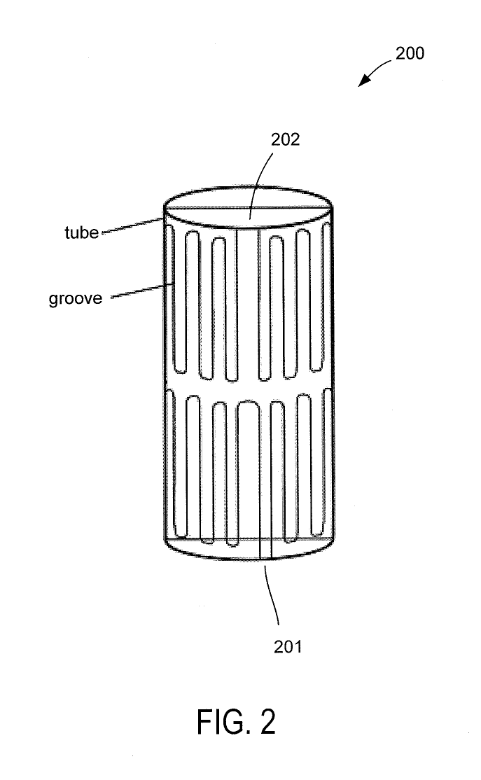

Another embodiment of the invention is shown in FIG. 2, which is a simplified diagram of a heating device 200. Again, this diagram is merely an example, which should not unduly limit the scope of the claims herein. One of ordinary skill in the art would recognize other variations, modifications, and alternatives. At least two grooves or channels are machined or ground into the first surface of the first tube, in a serpentine shape or like configuration. The serpentine shape allows both ends of the heating elements placed therein to exit from one end 201, 202 of the heater. As shown, the heating device includes two heating elements, but may include more or less according to a specific embodiment. Again, one of ordinary skill in the art would recognize other variations, modifications, and alternatives.

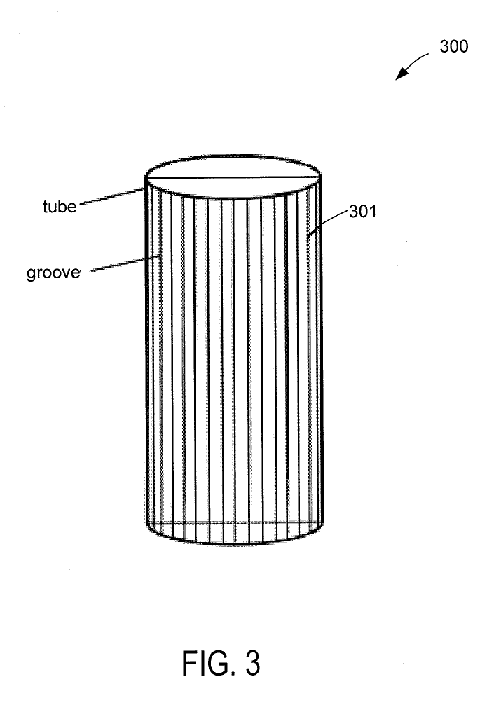

Yet another embodiment of the invention is shown in FIG. 3, which is a simplified diagram of a heating device 300. Again, this diagram is merely an example, which should not unduly limit the scope of the claims herein. One of ordinary skill in the art would recognize other variations, modifications, and alternatives. A plurality of linear grooves or channels are machined or ground into the first surface of the first tube. At least two heating elements are placed within the grooves or channels in the first surface of the first tube. In another embodiment, the grooves or channels have a helical component rather than being purely linear.

In an embodiment, the first and second tubes are placed within one or more additional tubes or sleeves. In an embodiment, a tube or sleeve is nestingly inserted within the second surface of the first tube. In an embodiment, a tube or sleeve is slipped over the first surface of the second tube. The additional tubes or sleeves may comprise a metal or alloy such as steel, stainless steel, an iron-based alloy, INCONEL 718, HASTALLOY X, or a nickel-based alloy. The radial or annular clearance between the first and/or second tubes and any additional tubes is less than 0.1 inch, and preferably below 0.02 inch, and even more preferably below 0.01 inch. A clearance less than 0.002 inch or an interference fit may be provided between the first and/or second tube and at least one additional tube or sleeve, and the parts assembled by heating the outer tube to a temperature greater than that of the inner tube by 10 to 500 degrees Celsius and sliding them together and/or by pressing the tubes over one another.

In some embodiments, the inner diameter of the heater is smooth and uniform, substantially free of gaps or voids, with no regions that have asperities or other features that produce a local inner diameter less by more than 0.005 inches or greater by more than 0.040 inches than the mean inner diameter. In a specific embodiment, the inner diameter of the heater is substantially free from any imperfections that can lead to failure and/or damage during operation of the high pressure apparatus. In some embodiments, the outer diameter of the heater is smooth and uniform, with no regions that have asperities or other features that produce a local outer diameter larger by more than 0.005 inches or less than 0.040 inches than the mean outer diameter, with the possible exception of one or more removable collars, described below.

The heating elements may be disposed in grooves or channels in the first surface of the first tube, and/or may lie within the annular space between the first and second tubes. Furthermore, the heating elements may be disposed in grooves or channels in the second surface of the first tube. In an embodiment, the heating elements may be disposed in grooves or channels in the second surface of the second tube. In an embodiment, the heating element is separated from at least one of the first tube and the second tube by an insulating coating. The coating may be deposited on at least one of the heating element, the first surface of the first tube, and the second surface of the second tube. The coating may comprise at least one of alumina and yttria-stabilized zirconia. A bonding adhesion layer (e.g., nickel aluminum, nickel aluminum chromium yttrium (NICRALY)) may also be used to improve bonding between the coating and the first tube and/or second tube. In another embodiment, the heating element is separated from at least one of the first tube and the second tube by a glass or ceramic structure, for example a tube. The glass or ceramic structure may comprise at least one of silica, alumina, mullite, or magnesia.

In an embodiment, the groove or channel and/or the annular space between the first and second tubes is filled with a filler material such as cement, and includes one or more heating element disposed within the cement material. In an embodiment, the filler cement material is castable or settable, such that it can be poured or flowed as a liquid and then hardened into a solid. In an embodiment, the cement material has a relatively high density and/or a low porosity. In another embodiment, the cement material has a relatively high alumina content. The use of suitable cement material as a filler in the annular space between the first and second tubes helps transfer internal pressures from the first tube to the second tube during operation. Suitable cement material may also be used to hold the glass or ceramic structure used to confine the heating element(s) in place within a groove or channel. Furthermore, the cement material may also be used as an encapsulant to directly contain or envelop the heating elements within the grooves or channel, potentially providing electrical insulation between the heater tube and the heating element. The filler material comprises no more than 10% of the overall heater by volume. In another embodiment, the filler material comprises no more than 5% of the overall heater by volume. In another embodiment, the filler material comprises no more than 2% of the overall heater by volume. In another embodiment, the filler material comprises no more than 1% of the overall heater by volume. In yet another embodiment, the heater is completely free of filler material.

Suitable cement material can be selected based on compressive fracture, further densification, and/or creep of a finished part made from the cement being negligible under operating conditions. In one embodiment, the cement material comprises castable, high-alumina content cement. In a second embodiment, the cement material has a relative density greater than 75% in comparison to its theoretical maximum density. In a third embodiment, the cement is selected for a relative density in a range selected from: 75-80%, 80-85%, 85-90%, 90-95%, and greater than 95% in comparison to the theoretical maximum density of the cement material.

Non-limiting examples of cements include alumina and magnesium oxide compounds. In an embodiment, the cement includes alumina that is present in an amount in a range of from 70-80 wt. %. In an embodiment, the cement includes alumina that is present in an amount greater than 50 wt. %. In an embodiment, the cement consists essentially of alumina and a binding compound. In an embodiment, the cement includes aluminum, magnesium, and at least one Group V metal on the periodic table. In an embodiment, the cement consists essentially of alumina and magnesium oxide. In an embodiment, the solid particulate for use in the cement has a surface coating that relatively increases the wetting and decreases void formation. Suitable cements are commercially available as AREMCO 575N and AREMCO 576N by Aremco Products, Inc. (Valley Cottage, N.Y.).

In some embodiments, the heater includes a plurality of heating elements that cooperate with each other to define a plurality of temperature-controllable heating zones, or hot zones. Each heating element includes one or more electrical leads. In some embodiments, as illustrated in FIGS. 1 and 2, the heating elements defining each heating zone are wound such that both ends, or both leads, of the same heating element exit from a single end of the structure. In an embodiment of a heater with two temperature-controllable heating zones, a pair of heating element ends or leads can exit from opposing ends of the heater. In another embodiment with two temperature-controllable heating zones, a pair of heating element ends or leads can exit from the same end. In embodiments having more than two hot zones, the heating element ends or leads can exit the heater from one end, from either end, or from various points along the outward facing surface of the first tube or second tube.

In a specific embodiment, the power density of the heater can be determined by controlling such factors as the winding density or the winding pitch, the selection of materials for use in the heating elements, the local cross sectional area of the heating element, and the like. In an embodiment, the winding density of the heating elements is relatively uniform, with variations of less than about 25%. In another embodiment, the winding density has variations of less than about 10%. In an embodiment, some portions of the heater have a higher winding density relative to other portions. In an embodiment, the end portions of the heater can have a relatively higher winding density relative to the middle portions of the heater. Controlling the power density allows for compensation of a higher heat loss rate at the ends relative to the region between the ends. In an embodiment, the temperature distribution is uniform over the length of the heater. In an embodiment, the winding density defines a gradient running from an end of the heater to the other and/or defines a temperature distribution pattern. In an embodiment, the temperature is relatively uniform within two or more axially-spaced hot zones, with a smooth transition in the temperature between adjacent zones. In some embodiments, the pitch can be selected to prevent, minimize, or eliminate wall nucleation during a high pressure crystal growth process.

Examples of suitable resistive heating elements and/or members include one or more of a wire, a ribbon, a coil, a foil, a rod, or any deposited or formed materials and/or any combination of these. One or more resistive heating elements can be wound around the axis in the groove or channel. The heating element thermally communicates with the first tube. In the case that either the first tube or the second tube is electrically conducting, the heater element is electrically insulated from the first tube and/or the second tube. The winding can be a spiral, a helix, a double helix, among others. Some embodiments include quadruple or higher helices. A double helical winding allows for two ends of the heating element to exit from the same end of the housing. A quadruple helix allows for the ends of two independent heating elements to exit from the same end of the housing. Multiple windings of a plurality of heating elements allows for zone control of the heating elements as disclosed further herein. In an embodiment, the cross-sectional area of the heating element is constant along its length. In another embodiment, the cross-sectional area of the heating element varies along its length. An increase in the cross sectional area in one segment of the heating element will decrease the heating power density in this segment. Variation of the local heating power density of the element can be useful with double- or multiple-helix wound heating elements. For example, application of electrical current to a first heating element applies heating power primarily to a first heating zone, while application of electrical current to a second heating element applies heating power primarily to a second heating zone, even though both heating elements are both present in at least one zone in the form of a wound double-helix or a multiple-helix.

Heater segments with different cross-sectional areas can be joined by welding, ultrasonic welding, ultrasonic splicing, resistance welding, brazing, crimping, clamping, or the like, including combinations. In another embodiment, the cross sectional area of a section of the heater segment is increased by twisting or otherwise electrically contacting one or more additional segments of wire with a first segment of wire. In yet another embodiment, the cross sectional area of a section of the heater segment is decreased by drawing a section of heater wire through a die. In still another embodiment, the cross sectional area of a section of the heater segment is decreased by trimming an edge portion of heater ribbon by means of a laser or a water jet. In an embodiment, the heating element includes a resistive heating wire or ribbon made from KANTHAL A-1, which is a trademark of a product sold by Kanthal AB, Sweden. The heating element winds on the first tube, thereby placing it in thermal communication with the first tube. In an embodiment, an electrically insulative coating and/or cement can be used on the heating elements to electrically isolate the heating elements from the first tube. The electrically insulative coating or cement can also be used to electrically isolate the heating elements from each other, and, optionally, from the first tube. In an embodiment, the heating element comprises a wire or ribbon fabricated from a nickel-chromium alloy. In another embodiment, the heating element comprises graphite. In an embodiment, the graphite is machined to fit precisely within a slot cut into or all the way through the first tube. Of course, there can be other variations, modifications, and alternatives. In still another embodiment, the heating element comprises gallium metal, which may be injected as a liquid to completely fill at least one groove between the first and second tubes. Other suitable materials that flow and fill at least one of the grooves can be used. Of course, there can be other variations, modifications, and alternatives.

Moreover, the present invention can also use heating elements using thick film and/or thin film techniques. That is, the heating element can be formed using a deposition process of filling a metal material within the groove or channel using plating (e.g., electroless, electrolytic), sputtering, evaporation (e.g., thermal, electron beam) chemical vapor deposition, or paste and/or printing techniques. Other techniques can include forming techniques using damascene techniques. Other metals that can be used to form the heating element include platinum, nickel, iron, chromium, titanium, tungsten, molybdenum, niobium, tantalum, any combinations, and alloys thereof. Again, there are other alternatives, variations, modifications.

Examples of suitable electrically insulative coatings include ceramic materials, e.g., magnesium oxide. In one embodiment, the electrically insulative coating is a multi-layered structure. In another embodiment, the multi-layered coating or structure has a composition that differs in a linear or non-linear fashion across its thickness to define a concentration gradient, e.g., one or more layers of yttria-stabilized zirconia (YSZ) and of alumina, which can be separated by a layer of a mixture of YSZ and alumina. Furthermore, the multi-layered structure may include one or more layers of YSZ, alumina, and/or a mixture thereof. The layered structure may include a ceramic insulating material deposited by, for example, plasma spraying or by electron-beam physical vapor deposition.

In a specific embodiment, as shown in FIG. 3, the heating elements comprise linear ribbons or wires placed within linear grooves or channels in the first surface of the first tube. One or more of the heating elements may comprise different values of resistance per unit length, for example, two dissimilar metals, joined together along their length. The two dissimilar metals may have different electrical resistivities, so that heat may be preferentially deposited around the metal with a high resistivity. In an embodiment, the portion of the ribbon or wire with a high electrical resistivity is selected from a suitable material such as products sold under the tradename of Kanthal A-1 by Kanthal AB, Sweden, a nickel-chromium alloy, an Fe—Cr—Al alloy, or a chromium alloy, and others. In an embodiment, the portion of the ribbon or wire with a low electrical resistivity from a suitable material including copper, copper-beryllium, a copper alloy, silver, gold, platinum, palladium, rhodium, titanium, cobalt, iron, nickel, molybdenum, or tungsten. In an embodiment, the dissimilar metals are joined by means of a butt weld. In another embodiment, the dissimilar metals are joined by at least one of a spot weld, a resistance weld, a laser weld, an electron-beam weld, an arc weld, and an ultrasonic weld. Of course, there are other variations, modifications, and alternatives.

In a specific embodiment, one or more of the heating elements, heating element ends, or electrical leads, emerge from the heater through notches or apertures cut into the second tube. The heating elements, ends or leads, where they emerge, can be insulated from conductive ground faults, such as the first tube, and from each other, by an electrically insulative article. In an embodiment, the electrically insulative article comprises woven alumina or fiberglass sleeving. In another embodiment, the electrically insulative article comprises one or more sections of ceramic or glass tubing. In yet another embodiment, the electrically insulative article comprises ceramic or glass beads. An end ring can be secured or attached to an end of the heater, after the heater is formed in the annular space. Of course, there can be other variations, modifications, and alternatives.

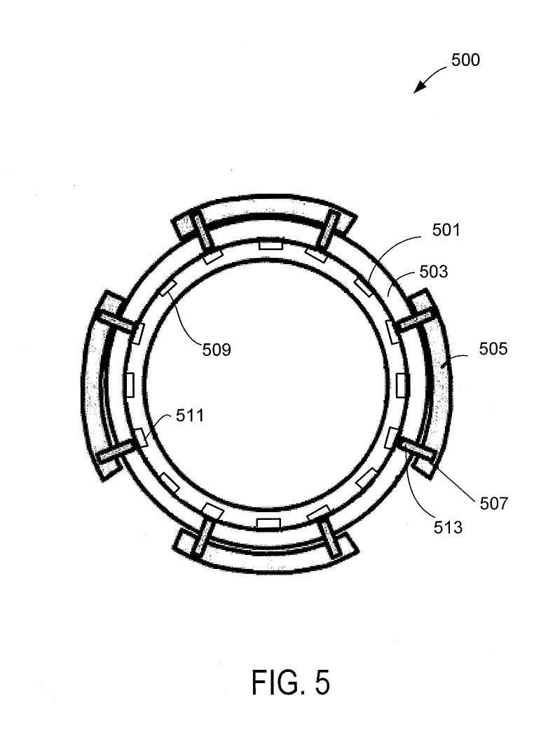

In a specific embodiment, electrical contact to the ends of the heating elements is provided by one or more external fixtures, collars, or end rings. An exemplary embodiment is shown in FIG. 5, which is a top-view diagram 500 of a connector device for a heater device according to a specific embodiment. A first set of heating elements, shown by reference numeral 509, comprise a high-resistance-per-unit-length metal within a first region of the heater and a low-resistance-per-unit-length metal within a second region of the heater. As shown, the first set of heating elements is spatially disposed as strips or wires along a length of the tube according to a specific embodiment. In the discussion below strips will be taken to refer to either strips or wires. Each of the strips is separated by a predetermined spacing according to a specific embodiment. A second set of heating elements, shown by reference numeral 511, comprise a low-resistance-per-unit-length metal within a first region of the heater and a high-resistance-per-unit-length metal within a second region of the heater. As shown, the second set of heating elements is spatially disposed as strips along a length of the tube according to a specific embodiment. Each of the strips is separated by a predetermined spacing according to a specific embodiment. In a specific embodiment, the first set of heating elements and the second set of heating elements can form an interdigitated structure or the first set may run partially down a length of the tube and the second set may run partially down a length of the tube from the opposite direction to form two heating zones. Although two heating zones have been discussed here, more than two heating zones, for example three or four heating zones, may be established using the concepts discussed in this document.

In a specific embodiment, the heating elements are electrically coupled using a collar structure 505. According to a specific embodiment, the collar 505 comprises contacts with one or more of the heating elements surrounding the heater near one end. The collar may make electrical contact 507 with one, two, or more of the heating elements of one type. Electrical contact between the collar and heating element(s) may be made through holes 513 in the second tube. A second collar may be placed in proximity to the first collar in order to make contact with a second set of heating elements. Corresponding collars may be provided at the opposite end of the heater. Heating power may be applied to the first region of the heater by running electrical current through the first set of heating elements via the appropriate collars. Heating power may be applied to the second region of the heater by running electrical current through the second set of heating elements via the appropriate set of collars. The elements within the collars may be connected in series or in parallel, so that all the heating elements within each of the first and second sets are configured in series or in parallel, or a subset of the heating elements may be in parallel.

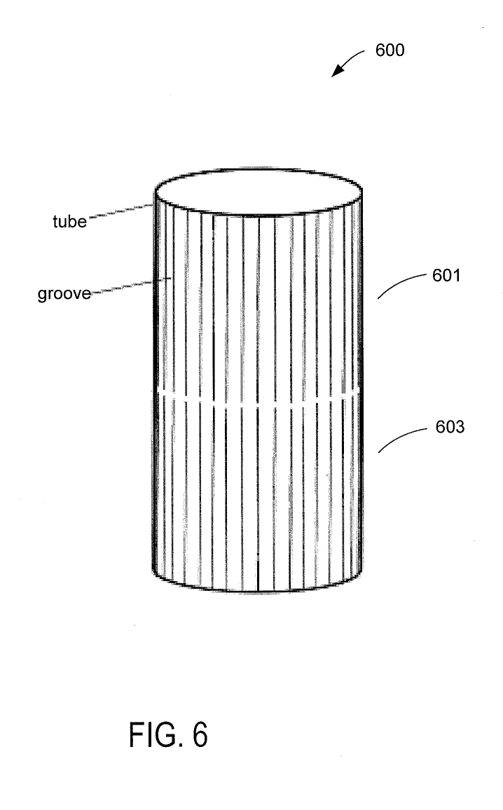

FIG. 6 is a simplified diagram of yet an alternative embodiment of a heating device 600 according to an embodiment of the present invention. As shown, the heating elements comprise linear ribbons or wires placed within linear grooves or channels in the first surface of the first tube that run a portion of the length of the tube, for example, one set of grooves or channels for the growth zone 601 and another set for the nutrient zone 603. In a specific embodiment, each of the zones may be independently regulated. Additionally, the plurality of groves and/or recessed regions are efficiently made using techniques known to one of ordinary skill in the art. Additionally, each of the heading elements include at least a pair of contact regions respectively coupling to a ground and positive potential according to a specific embodiment. Each heating element may comprise a suitable material such as products sold under the tradename of Kanthal A-1 by Kanthal AB, Sweden, a nickel-chromium alloy, an Fe—Cr—Al alloy, or a chromium alloy, and others.

In a specific embodiment, the heating elements may be separated from at least one of the first tube and the second tube by a glass or ceramic tube according to a specific embodiment. The glass or ceramic tube may comprise at least one of silica, alumina, mullite, or magnesia. In a specific embodiment, the heating element is embedded in densified ceramic powder and encased in a metal sheath. In a specific embodiment, the densified ceramic powder comprises MgO and the metal sheath comprises steel. In a specific embodiment, the distal end of the heating elements, with respect to the end of the first tube, is welded or brazed to the sheath, forming a single-ended tubular heater. In another specific embodiment, the end of the heating element is placed in electrical contact with the first tube. The electrical contact to the first tube may be provided by mechanical compression, thermal compression bonding, spot welding, arc welding, cold welding, brazing, or the like. Electrical connections to the ends of the heating elements proximal to the ends of the first tube may be made by means of a collar, as shown in FIG. 5. Of course, there are other variations, modifications, and alternatives.

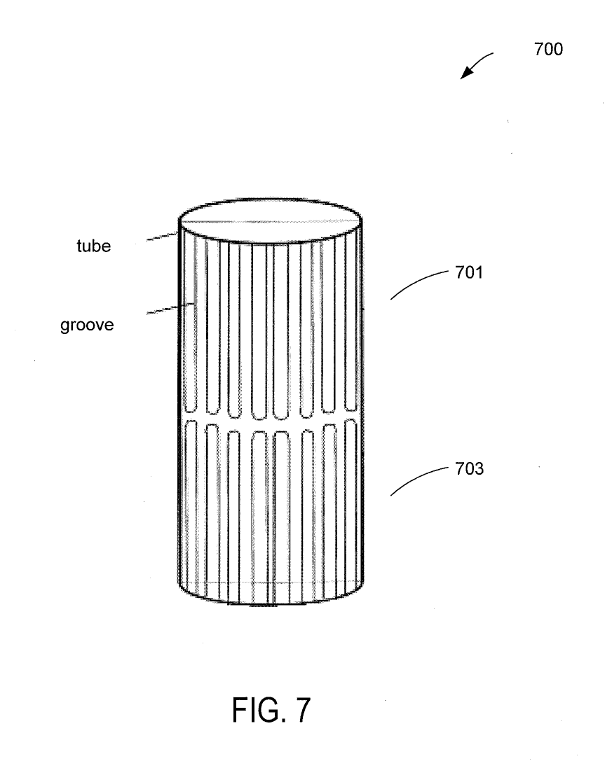

FIG. 7 is a simplified diagram of an alternative embodiment of a heating device 700 according to an embodiment of the present invention. Again, this diagram is merely an example, which should not unduly limit the scope of the claims herein. One of ordinary skill in the art would recognize other variations, modifications, and alternatives. At least two grooves or channels are machined or ground into the first surface of the first tube, in a U shape. Two sets of U-shaped grooves or channels in the first surface of the first tube that run a portion of the length of the tube, for example, one set of grooves or channels for the growth zone 701 and another set for the nutrient zone 703. In a specific embodiment, each of the zones may be independently regulated. Additionally, the plurality of groves and/or recessed regions are efficiently made using techniques known to one of ordinary skill in the art. Each heating element may comprise a suitable material such as products sold under the tradename of Kanthal A-1 by Kanthal AB, Sweden, a nickel-chromium alloy, an Fe—Cr—Al alloy, or a chromium alloy, and others, and may be furnished in the form of a tubular heater bent into a U shape. The U shape allows both ends of each heating elements placed into the groove or channel to exit from one end of the heater. Electrical connections to the ends of the heating elements proximal to the ends of the first tube may be made by means of a collar, as shown in FIG. 5.

In some embodiments, a length of no longer than about ten millimeters characterizes the cylindrical structure of the heater from an inner portion of the cylindrical structure and an outer portion of the cylindrical structure. In other embodiments, a length of no longer than about six millimeters characterizes the cylindrical structure of the heater from an inner portion of the cylindrical structure and an outer portion of the cylindrical structure. In still other embodiments, a length of no longer than about four millimeters characterizes the cylindrical structure of the heater from an inner portion of the cylindrical structure and an outer portion of the cylindrical structure. In yet other embodiments, a length of no longer than about three millimeters characterizes the cylindrical structure of the heater from an inner portion of the cylindrical structure and an outer portion of the cylindrical structure. Of course, there can be other variations, modifications, and alternatives.

In a specific embodiment, the present heater and method can be used in conjunction with the apparatus disclosed in U.S. 2006/0177362 and U.S. 2008/0083741, which are incorporated by reference herein, and with the apparatus disclosed in co-pending application Ser. No. 12/133,364 (Attorney Docket No. 027364-000300US), commonly assigned and hereby incorporated by reference herein. In a specific embodiment, the present apparatus may include a first tube and a second tube structure with multiple heating elements disposed in between them. In a specific embodiment, the second tube has an inner surface that defines a volume in which a first tube is coaxially nested on a defined axis. The second tube inner surface is spaced from the first tube outer surface to define the elongate toroid, annular space, or gap therebetween. The tubes have a first end and a second end axially spaced from the first end and relatively up therefrom.

In a specific embodiment, a first resistive heating element, a second resistive heating element, and a third resistive heating element are disposed within the annular space. Alternatively, more than three resistive heating elements can also be disposed within the annular space according to other embodiments. In a specific embodiment, the heating elements are spirally wound. The windings are spaced from each other by a winding distance or pitch, for the third resistive heating element. The first and second resistive heating elements extend axially different lengths from each other, which can allow for finer tuning of the temperature profile during use. Each of the first and second resistive heating elements may constitute a double-helix, allowing for both the leads of each heating element to exit from the same end of the heater. The third resistive heating element can exit from a side of the heater or from either end.

In a specific embodiment, the heating elements include 18-gauge metal wire that can operate with 208 volts, and 4000 Watts max, but can be other configurations, including wire gauges and power. An electrical lead for the third resistive heating element exits at the bottom of the heater. Other electrical leads for the other heating elements are also included. A relatively thicker cross section of the leads, relative to the heating elements, reduces electrical resistance and the heat associated with electrical resistance. In a specific embodiment, the relatively increased thickness is achieved by contacting additional lengths of wire to the lead wire outer surface to form a wire bundle. The wire bundle may be twisted while avoiding kinks, narrow spots, and the like, which would create localized electrical resistance and the heat associated therewith during use. In another embodiment, the lead is folded back on itself in a zig-zag to increase the cross-sectional thickness. Of course, there can be other variations, modifications, and alternatives.

The first tube may be coated with an electrically non-conductive ceramic coating. The electrically insulating ceramic coating electrically isolates segments of the heating element from at least the first tube. In a specific embodiment, the coating is a multi-layered composite structure, but can be others. The composite structure includes layers of yttria-stabilized zirconia (YSZ) and alumina separated by a plurality of layers of differing mixtures of YSZ and alumina, and the like. Furthermore, a bonding adhesion layer may also be used to improve bonding between the coating and the first tube and/or second tube. An example of an adhesion layer that may be used is a nickel-aluminum alloy layer, nickel aluminum chromium yttrium (NICRALY), among others

The annular space or gap is substantially free from any filler material according to a specific embodiment. In a specific embodiment, an interface region provided within a vicinity of the annular region is substantially free from one or more voids and/or gaps capable of causing a failure including a crack and/or creep condition during an operation condition. Of course, there can be other variations, modifications, and alternatives.

The heating elements are in thermal communication with the first tube, and remain electrically insulated from both the first tube and the second tube according to a specific embodiment. Starting from the top and working down, the arrangement of sets of heating elements defines several heat zones. In a specific embodiment, the heat zones may include an uppermost first zone, a growth zone, a baffle gap zone, and a charge (or source) zone. In another embodiment, the heat zones may include a charge (or source) zone, a baffle gap zone, and a growth zone. Other zones may be added, removed, or used in any combination without departing from the scope of this invention. When a capsule is inserted into the volume defined by a first tube inner surface, an internal baffle aligns with the baffle gap zone. The baffle defines two chambers inside the capsule, one for charge and one for growth. The two chambers communicate through the perforated baffle. The first tube inner surface may have one or more characteristics as discussed further herein, particularly with reference to the release characteristics of the removable capsule.

In a specific embodiment, the capsule suitable for insertion inside the first tube is formed from a precious metal. Examples of precious metals include platinum, iridium, gold, or silver. Other metals can include titanium, rhenium, copper, stainless steel, zirconium, tantalum, nickel, chromium, vanadium, alloys thereof, and the like. In one embodiment, the metal functions as an oxygen getter. Suitable capsule dimensions may be greater than 2 cm in diameter and 4 cm in length. In one embodiment, the dimension of the diameter is in a range selected from any of: 2-4 cm, 4-8 cm, 8-12 cm, 12-16 cm, 16-20 cm, 20-24 cm, and greater than 24 cm. In a second embodiment, the ratio of the length to diameter of the capsule is greater than 2. In yet another embodiment, the ratio of length to diameter is in a range of any of: 2 to 4, 4 to 6, 6 to 8, 8 to 9, 9 to 10, 10 to 11, 11 to 12, 12 to 14, 14 to 16, 16 to 18, 18 to 20, and greater than 20. Of course, there can be other variations, modifications, and alternatives.

In a specific embodiment, the growth zone volume has approximately twice the charge zone volume. The electrical circuits for each heating element segments are independently controlled. Independent control provides flexibility to achieve and maintain a heat deposition profile along the capsule height. A physical discontinuity between the second and third heater segments, from the top, produces a local dip in temperature near a baffle plate disposed in the capsule and separating the charge zone from the growth zone. In one embodiment, the charge zone and the growth zone are isotherms at temperatures that differ from each other. The baffle zone has a temperature gradient over a relatively small distance between the charge zone and the growth zone isotherms. The winding patterns of the heating elements, and the resultant isotherms with minimal temperature gradient spacing therebetween minimize or eliminate wall nucleation inside the capsule. In one embodiment, the growth zone may be at the bottom and the charge zone at the top. In another embodiment, the growth zone may be at the top and the charge zone at the bottom. Such configurations may be based on specific chemistries and growth parameters.

Again, the present heater is disposed in an apparatus that includes a vessel. Attachable to the top end of the vessel is a first end cap, and to the bottom end is a second end cap. A plurality of fasteners secure the end caps to the vessel ends.

Within the vessel, a thermal insulation medium lines the vessel inner surface and contacts the outer surface of the heater. Examples of thermal insulation medium include but are not limited to zirconium oxide or zirconia. First and second thermal insulation medium caps are located proximate to the ends of the heater inside the vessel. An annular plug may comprise stacked disks, but may alternatively be an annulus surrounding the cap. The plug optionally can be disposed on at least one end and within a cavity between the end of the heater and the end ring to reduce axial heat loss. The plug is commercially available from a variety of sources including Thermal Ceramics Worldwide (Augusta, Ga.), under the trade name KAOWOOL.

In a specific embodiment, Nichrome® heating elements are embedded in a filler material. The layer of thermal insulation medium is placed around the heater with the ends receiving the plug. Alternative plug materials may include magnesium oxide, salts, and phyllosilicate minerals such as aluminum silicate hydroxide or pyrophyllite. Of course, there can be other variations, modifications, and alternatives.

In a specific embodiment, the apparatus can be used to grow crystals under pressure and temperature conditions desirable for crystal growth, e.g., gallium nitride crystals under related process conditions. The high-pressure apparatus can include one or more structures operable to support the heater radially, axially, or both radially and axially. The support structure in one embodiment thermally insulates the apparatus from the ambient environment, and such insulation may enhance or improve process stability, maintaining and controlling a desired temperature profile.

In an alternative embodiment, the heater includes a first tube and a heating assembly. The heating assembly can have differing cross-sectional shapes such as a horseshoe and an oval cross-section, respectively. The first tube has a housing or outer surface that defines at least one groove or channel. Each heating assembly includes a second outer tube, a central heating element, and, optionally, an electrically insulative ceramic filler disposed between the second tube and the heating element. Grooves or channels of differing depths can be used in the same or in differing heaters according to embodiments of the invention. In addition, grooves with differing opening widths can be used. For example, the opening width of an opening is relatively narrower than the opening width of another opening. As the defined volume of the groove or channel moves radially inward while retaining curved sidewalls, in one embodiment the opening width may decrease. If the opening width decreases to less than the width of the heating element, the heating element (or a second tube) can be inserted axially from, for example, an end. In alternative embodiments, the width can decrease to zero.

The heating assembly nestingly fits into the groove or channel according to a specific embodiment. The heating assemblies can be a CALROD heating assembly, such as those sealed element devices using a Nichrome wire in a ceramic binder, sealed inside a metal shell according to a specific embodiment. The heating assembly includes an optional second, outer tube, a central heating element, and, optionally, an electrically insulative ceramic filler disposed between the second tube and the heating element.

Residual space or porosity between the heating element and the second tube can be removed or minimized by swaging the second tube down onto the heater with surrounding ceramic filler to fabricate the assembly. The channel or groove can complement the shape of the heating assembly. The groove surface can be machined, ground, or polished before insertion of the heating element to provide a smooth finish, tight tolerance, and enhanced thermal communication. The groove can have a serpentine or U shape, with the heating assembly bent into a corresponding serpentine or U shape so as to fit into the groove, so that one or more heating assemblies can be used to provide even heating over the inner portion of the first tube.

In a specific embodiment with the heater assembly, the space in the groove between the first tube surface and the outer surface of heating assembly is substantially free from voids and/or gaps and can be either electrically conductive or electrically insulative. Some embodiments may include adding additional cement material at the corners. This additional cement serves to round out the corners, enhancing thermal and/or structural integrity.

In yet another embodiment of a heater assembly without the second tube the assembly comprises a heating element, which is disposed inside the space in the groove or channel. Optionally, a filler material (cement) is disposed between the heating element and the first tube surface. The filler material may be cured. In an example wherein the filler material is electrically conductive, the heating element is first coated with an electrically insulating material of sufficient dielectric strength.

In another embodiment, rather than the cement material, the remaining space in the groove can be filled with the same material as the first tube. The tube filler material can be deposited electrochemically, by powder metallurgy, by physical vapor deposition, by chemical vapor deposition, or the like.

In a specific embodiment, the heater may include a plurality of differing heating elements, defining two, three or more hot zones in which the temperature is controllable. Multiple hot zones can be accommodated. The first tube is coated with a first insulating ceramic layer. A controller communicates from and to a plurality of heating element segments comprising fractional or multiple windings wrap around the thermally conductive and electrically insulated first tube during formation. A common segment is also present to complete the circuit. Additional insulating ceramic layers can be placed on top of one or more of the heating element segments, electrically isolating them from the leads to controller. One or more electrical contacts can be used to connect to ends of the heating element segments.

The electrical contacts can be fabricated from a relatively heavier gauge material and/or a lower resistivity material, so that most of the heat generation degrees occurs preferentially within the heating element segments rather than in the electrical leads. The electrical leads can be attached to the heater segments by spot welding, arc welding, ultrasonic welding, brazing, quick connect fasteners, screw clamps, or the like. The one or more additional ceramic coatings can reduce or eliminate shorting of the electrical lead wires to the other heater segments. A castable ceramic cement material may encase, or be cast onto, the above-described assembly. The second tube may be placed over the assembly to complete one heater according to an embodiment of the invention.

The controller communicates with sensors and with the heating elements according to a specific embodiment. Suitable sensors include temperature sensors and/or pressure sensors located proximate to the zones being sensed. In one embodiment, the temperature sensor comprises a thermocouple. The presence of multiple zones allows for a desirable amount of control of temperature distribution within the heater by the controller, and ultimately for control over heat distribution within the first tube and/or the reaction capsule (if present). In addition, the electrical power to each segment can be programmed as a function of time, so that the controller can manipulate the temperature distribution within the heater. Such control over temperature distribution is useful for a variety of crystal growth methods, such as a hydrothermal crystal growth method.

In a specific embodiment of a crystal growth process, energy supplied to the heating element causes thermal energy to flow into the first tube to a capsule disposed within a region of the first tube. The heat provided increases the capsule temperature to be in a range of greater than 500 degrees Celsius, and can be sufficient to generate pressure within the capsule to be in a range of greater than 500 MPa as a response to the increase in temperature. In operation, the materials comprising the heater transfer internal pressures from the inner diameter of the heater outward to the outer diameter of the heater during operation, thus minimizing heater volume changes/deformation. As the heater is substantially incompressible, it helps maintain the volume and/or shape of the capsule. In a specific embodiment with the use of end rings secured to the first ends of the tubes, the volume and/or shape of the heater can be further secured in operation.

As the volume of the first tube is minimally changed and its shape is minimally deformed, the heater can be reused for subsequent high-pressure high temperature operations. In one embodiment, the change in the internal volume of the first tube (as defined by the interior of the first tube and the two ends) is less than 5 vol. %. In a second embodiment, the first tube incurs an internal volume change of less than 2%. In a third embodiment, a volume change of less than 1%. In one embodiment, the change in the external volume of the first tube (as defined by the interior volume of the housing) is less than 5 vol. %. In a second embodiment, the first tube incurs an external volume change of less than 2%. In a third embodiment, an external volume change of less than 1%. As the heater inner (first) tube incurs minimal volume change and experiences few or no gaps, cracks, or discontinuities, a capsule placed in the heater for processing at high pressure/high temperature can be slidingly removed from the heater after the operation is completed. As used herein, “slidingly removed” means that the capsule can slide off the inside surface of the first tube without the need to use excessive force and without permanent damage to the heater. In one embodiment, the capsule is hydraulically loaded on one end, e.g., with the use of a hydraulic piston, to slide out from the inside of the first tube. A mechanical restraint may be provided in order to prevent removal of the heater from a pressure transfer or thermal insulation material. After the capsule is slidingly removed from the first tube after the initial operation, the heater can still be reused multiple times.

In some embodiments, each of the heating elements include at least a pair of heating members that may run substantially in parallel to each other. The pair of heating members include at least a first member and a second member according to a specific embodiment. Depending upon the embodiment, each of the heating members is a wire and/or ribbon and/or coating. A spacing “x” is provided between the first member and the second member. Depending upon the embodiment, spacing x may be constant, change slightly, or change significantly according to the specific application. In a specific embodiment, the spacing x is no greater than about 50% of “d,” which is defined as the diameter of the inner cylinder device. In alternative embodiments, the spacing d is no greater than about 25% or 10% or 5% of d, again the diameter of the inner cylinder device. Of course, there can be other variations, modifications, and alternatives.

The embodiments described herein are examples of compositions, structures, systems and methods having elements corresponding to the elements of the invention recited in the claims. This written description enables one of ordinary skill in the art to make and use embodiments having alternative elements that likewise correspond to the elements of the invention recited in the claims. The scope thus includes compositions, structures, systems and methods that do not differ from the literal language of the claims, and further includes other compositions, structures, systems and methods with insubstantial differences from the literal language of the claims. As an example, the term “heater” is generally interpreted to include one or more zones or a single heater element or multiple heater elements, as well as other variations, modifications, and alternatives. While only certain features and embodiments have been illustrated and described herein, many modifications and changes may occur to one of ordinary skill in the relevant art. The appended claims are intended to cover all such modifications and changes.

What is claimed is:

1. A heater for processing materials in supercritical fluids at high pressure and high temperature, comprising:
at least one inner tube member comprising a first region and a second region, the inner tube member comprising an outer surface region and an inner surface region;
at least two heating elements spatially disposed respectively at least within the first region and the second region;
a thickness of at least one insulating material overlying the at least two heating elements, the thickness of insulating material comprising a first inner surface region and a first outer surface region;
a cylindrical structure provided by at least the inner tube member, the two heating elements, and the thickness of insulating material to form a substantially incompressible sandwiched structure including at least the inner tube member, two heating elements, and thickness of insulating material, the cylindrical structure being substantially free from one or more voids and/or gaps, the one or more gaps and/or voids being capable of causing a failure including a crack and/or creep condition during an operation condition;
a length of no longer than about ten millimeters characterizing the cylindrical structure from an inner portion of the cylindrical structure and an outer portion of the cylindrical structure; and
wherein the inner portion of the cylindrical structure and the outer portion of the cylindrical structure are electrically isolated from the at least two heating elements.

2. The heater of claim 1 wherein the inner portion of the cylindrical structure and the outer portion of the cylindrical structure are characterized by a length of no longer than about six millimeters from the inner portion of the cylindrical structure and to the outer portion of the cylindrical structure.

3. The heater of claim 1 wherein the inner portion of the cylindrical structure and the outer portion of the cylindrical structure are characterized by a length of no longer than about three millimeters from the inner portion of the cylindrical structure and to the outer portion of the cylindrical structure.

4. The heater of claim 1 wherein the insulating material comprises one or more coating materials.

5. The heater of claim 1 wherein the insulating material comprises a tube structure.

6. The heater of claim 1 wherein the substantially incompressible sandwich structure is configured to change in thickness from a first thickness during a first condition to a second thickness during a second condition, the first condition is characterized as an assembly condition and the second condition is characterized as a processing condition, the processing condition has a temperature of at least 450 Degrees Celsius.

7. The heater of claim 6 wherein the processing condition includes temperatures of a least 550 degrees Celsius.

8. The heater of claim 1 wherein the substantially incompressible sandwich structure is substantially free from any filler materials.

9. The heater of claim 1 wherein the heater is disposed within an inner region of a high pressure apparatus.

10. The heater of claim 1 wherein the at least two heating elements are spatially disposed respectively at least within the first region and the second region, each of the heating elements being configured as a double helix.

11. The heater of claim 1 wherein the at least two heating elements are spatially disposed at least within the first region and the second region, respectively, each of the heating elements being configured in a serpentine pattern.

12. The heater of claim 1 wherein the at least two heating elements are spatially disposed respectively at least within the first region and the second region, each of the heating elements being configured as in a U-shaped pattern.

13. The heater of claim 1 wherein the at least two heating elements are spatially disposed respectively at least within the first region and the second region, at least one of the heating elements being configured as a quadruple helix.

14. The heater of claim 1 wherein the at least two heating elements spatially are disposed respectively at least within the first region and the second region, each of the heating elements being configured as a plurality of strips running parallel down an axial direction, at least two of the plurality of strips comprising lengths of at least two different values of resistance per unit length, each of the heating elements configuring a plurality of strips in a spatially parallel manner and electrically parallel.

15. The heater of claim 14 wherein the electrical arrangement is configured to allow one or more of the plurality of strips to be operational while one or more of the plurality of strips is non-operational.

16. The heater of claim 1 wherein at least two heating elements are spatially disposed respectively at least within the first region and the second region, each of the heating elements being configured as a plurality of strips running parallel down an axial direction, at least two of the plurality of strips comprising lengths of at least two different values of resistance per unit length, each of the heating elements configuring a plurality of strips in a spatially parallel manner and electrically serial.

17. The heater of claim 1 wherein at least two heating elements are spatially disposed respectively at least within the first region and the second region, each of the heating elements being configured as a plurality of strips running parallel down an axial direction, at least two of the plurality of strips comprising lengths of at least two different values of resistance per unit length, each of the heating elements configuring the plurality of strips in a spatially parallel manner, and wherein at least two strips are configured to be in series electrically and wherein at least two sets of strips are configured to be in parallel electrically.

18. The heater of claim 1 wherein the inner surface of the heater and the outer surface of the heater each have a root-mean-square surface roughness of about 1 millimeter (mm) and less, wherein the inner surface of the heater is substantially free of gaps and voids, and wherein the second surface of the first tube has a root-mean-square surface roughness less than 0.1 millimeter, or less than 0.01 millimeter, or less than 0.001 millimeter.

19. The heater of claim 1 wherein the first surface of the second tube has a root-mean-square surface roughness less than 0.1 millimeter, or less than 0.01 millimeter, or less than 0.001 millimeter.

20. The heater of claim 1 wherein the inner surface of the heater and the outer surface of the heater each have a root-mean-square surface roughness of about 0.1 millimeter (mm) and less.

21. The heater of claim 1 wherein the inner surface of the heater and the outer surface of the heater each have a root-mean-square surface roughness of about 0.01 millimeter (mm) and less.

22. The heater of claim 1 wherein no region of the inner diameter of the heater has asperities or other features that produce a local inner diameter less by more than 0.005 inches than the mean inner diameter.

23. The heater of claim 1 wherein no region of the outer diameter of the heater has asperities or other features that produce a local outer diameter greater by more than 0.005 inches than the mean outer diameter.

24. The heater of claim 1 wherein each of the two heating elements is electrically isolated between the thickness of insulating material and the inner tube device.

25. The heater of claim 1 is configured to allow processing of a capsule to be free from failure or substantial deformation.

26. The heater of claim 1 wherein the cylindrical structure comprising a first zone and a second zone respective to the first heating element and the second heating element, the first zone and the second zone being spatially disposed respective to a first processing zone and a second processing zone of a capsule, the first zone being configured to provide a substantially uniform first temperature profile along the first processing zone and the second zone being configured to provide a substantially uniform second temperature profile along the second processing zone.

27. The heater of claim 1 further comprising an outer thickness of material overlying the two heating elements.

28. A heater for processing materials in supercritical fluids at high pressure and high temperature, comprising:
at least one inner tube member comprising a first region and a second region, the inner tube member comprising an outer surface region and an inner surface region;
at least two heating elements spatially disposed respectively at least within the first region and the second region;
a thickness of insulating material overlying the two heating elements, the thickness of insulating material comprising an inner surface region and an outer surface region;
an interface region provided between the outer surface region of the inner tube member and the inner surface region of the thickness of insulating material, the interface region being substantially free from one or more voids and/or gaps, the one or more gaps and/or voids being capable of causing a failure including a crack and/or creep condition during an operation condition;
a cylindrical structure provided by at least the inner tube member, the two heating elements, and the thickness of insulating material to form a substantially incompressible sandwiched structure including at least the inner tube member, two heating elements, and thickness of insulating material;
wherein the inner portion of the cylindrical structure and the outer portion of the cylindrical structure are electrically isolated from the at least two heating elements; and
wherein at least two heating elements are spatially disposed respectively at least within the first region and the second region, each of the heating elements being configured as a plurality of strips running parallel down an axial direction, at least two of the plurality of strips comprising lengths of at least two different values of resistance per unit length.

29. The heater of claim 28 wherein at least two heating elements are configured as a plurality of strips in a spatially parallel manner and are electrically in parallel.

30. The heater of claim 28 wherein at least two heating elements are configured as a the plurality of strips in a spatially parallel manner, and wherein at least two strips are configured to be in series electrically and wherein at least two sets of strips are configured to be in parallel electrically.

31. The heater of claim 30 wherein the parallel arrangement is configured to allow one or more of the plurality of strips to be operational while one or more of the plurality of strips is non-operational.

32. The heater of claim 29 wherein the parallel arrangement is configured to allow one or more of the plurality of strips to be operational while one or more of the plurality of strips is non-operational.

33. The heater of claim 28 wherein at least two of the heating elements are configured as a plurality of strips in a spatially parallel manner and are electrically in series.

34. A heater for processing materials in supercritical fluids at high pressure and high temperature, comprising:
at least one inner tube member comprising a first region and a second region, the inner tube member comprising an outer surface region and an inner surface region;
at least two sets of heating elements spatially disposed respectively at least within the first region and the second region;
a thickness of insulating material overlying the two sets of heating elements, the thickness of insulating material comprising a first inner surface region and a first outer surface region;
an interface region provided between the outer surface region of the inner tube member and the first inner surface region of the thickness of insulating material, the interface region being substantially free from one or more voids and/or gaps, the one or more gaps and/or voids being capable of causing a failure including a crack and/or creep condition during an operation condition;
a cylindrical structure provided by at least the inner tube member, the at least two sets of heating elements, and the thickness of insulating material to form a substantially incompressible sandwiched structure including at least the inner tube member, two sets of heating elements, and the thickness of insulating material;
wherein the inner portion of the cylindrical structure and the outer portion of the cylindrical structure are electrically isolated from the at least two heating elements; and
wherein the at least two sets of heating elements are spatially disposed respectively at least within the first region and the second region, each of the heating elements being configured as a plurality of strips running parallel down an axial direction, the ends of each of the plurality of strips distal with respect to the ends of the inner tube being placed in electrical contact with the inner tube.

35. The heater of claim 34 wherein at least two of the heating elements are configured as a plurality of strips in a spatially parallel manner, and wherein at least two strips are configured to be in series electrically and/or wherein at least two sets of strips are configured to be in parallel electrically.

36. Apparatus for processing one or more materials comprising: at least one heating element configured to transfer thermal energy to a process region within a capsule contained in a high pressure reactor, the high pressure reactor being capable of withstanding a pressure of about 0.2 GPa and greater, the heating element being spatially disposed within a vicinity of the capsule and characterized by a thickness of less than a predetermined amount to maintain an exterior region of the capsule substantially free from damage while the process region of the capsule is subjected to a pressure of about 0.2 GPa and greater.

37. Apparatus of claim 36 wherein the heating element is characterized by the thickness of less than the predetermined amount to have a deformation of less than about 2 mm.

38. Apparatus of claim 36 wherein the heating element is characterized by the thickness of less than the predetermined amount to maintain the exterior region of the capsule free from a deformation of greater than about 2 mm.

39. Apparatus of claim 36 wherein the predetermined thickness is 6 mm and less.

40. Apparatus of claim 36 wherein the predetermined thickness is 3 mm and less.

41. Apparatus of claim 36 wherein the heating element is configured around the exterior region of the capsule.

42. Apparatus of claim 36 wherein the process region comprises a gallium nitride containing crystalline material.

43. Apparatus of claim 36 wherein the deformation is less than about 0.5 mm.

44. Apparatus of claim 36 wherein the exterior region of the capsule is maintained substantially free from damage while the process region of the capsule is subjected to a pressure of about 0.5 GPa and greater.

45. A method for forming crystalline material, the method comprising:
using an apparatus for processing one or more materials comprising at least one heating element configured to transfer thermal energy to a process region within a capsule contained in a high pressure reactor, the high pressure reactor being capable of withstanding a pressure of about 0.2 GPa and greater, the heating element being spatially disposed within a vicinity of the capsule and characterized by a thickness of less than a predetermined amount to maintain an exterior region of the capsule substantially free from damage while the process region of the capsule is subjected to a pressure of about 0.2 GPa and greater; and
forming a gallium nitride crystalline material within one or more portions of the process region.

46. The method of claim 45 comprising using one or more portions of the gallium nitride crystalline material for manufacture of an optical or electronic device.
